(19) United States
(12) Patent Application Publication
(10) Pub. No.: US 2024/0186387 A1
(43) Pub. Date: Jun. 6, 2024

(54) VIA AND SOURCE/DRAIN CONTACT LANDING UNDER POWER RAIL

(71) Applicant: INTERNATIONAL BUSINESS MACHINES CORPORATION, ARMONK, NY (US)

(72) Inventors: Ruilong Xie, Niskayuna, NY (US); Min Gyu Sung, Latham, NY (US); Chanro Park, Clifton Park, NY (US); Kangguo Cheng, Schenectady, NY (US); Julien Frougier, Albany, NY (US)

(21) Appl. No.: 18/061,495

(22) Filed: Dec. 5, 2022

(51) Int. Cl. H01L 29/417; H01L 21/28; H01L 21/8238; H01L 23/528; H01L 27/092; H01L 29/06; H01L 29/423; H01L 29/66; H01L 29/775

(52) U.S. Cl. CPC H01L 29/41733; H01L 21/28123; H01L 21/823807; H01L 21/823814; H01L 21/823871; H01L 21/823878; H01L 23/5286; H01L 27/092; H01L 29/0673; H01L 29/42392; H01L 29/66439; H01L 29/775

(57) ABSTRACT

A microelectronic structure including a first nano device that includes a plurality of first transistors and the plurality of first transistors includes at least one first source/drain. A second nano device includes a plurality of second transistors and the second nano device is oriented parallel to the first nano device. The plurality of second transistors includes at least two second source/drains. A gate cut located between the first nano device and the second nano device. A source/drain contact connected to the at least one first source/drain and is connected to at least one of the second source/drains. A portion of the source/drain contact extends parallel to the first nano device and the second nano device.

### BACKGROUND

The present invention generally relates to the field of microelectronics, and more particularly to formation of source/drain contact bar at the location of the interconnect bar.

Nanosheet is the lead device architecture in continuing CMOS scaling. However, nanosheet technology has shown issues when scaling down such that as the devices become smaller and closer together, they are interfering with each other. With the number of devices being fit in a smaller area it is becoming harder to form the necessary contact with the proper alignment and spacing to prevent shorts from forming between the contacts.

### BRIEF SUMMARY

Additional aspects and/or advantages will be set forth in part in the description which follows and, in part, will be apparent from the description, or may be learned by practice of the invention.

A microelectronic structure including a first nano device that includes a plurality of first transistors and the plurality of first transistors includes at least one first source/drain. A second nano device includes a plurality of second transistors and the second nano device is oriented parallel to the first nano device. The plurality of second transistors includes at least two second source/drains. A gate cut located between the first nano device and the second nano device. A source/drain contact connected to the at least one first source/drain and is connected to at least one of the second source/drains. A portion of the source/drain contact extends parallel to the first nano device and the second nano device.

A microelectronic structure including a first nano device that includes a plurality of first transistors and the plurality of first transistors includes at least one first source/drain. A second nano device includes a plurality of second transistors and the second nano device is oriented parallel to the first nano device. The plurality of second transistors includes at least a second and third source/drains. A gate cut located between the first nano device and the second nano device. A first source/drain contact connected to the at least one first source/drain and is connected to at least the second source/drains. A portion of the source/drain contact extends parallel to the first nano device and the second nano device. A dielectric pillar located between the at least first source/drain of the first nano device and the second source/drain of the second nano device.

A method including the steps of forming a first nano device that includes a plurality of first transistors and the plurality of first transistors includes at least one first source/drain. Forming a second nano device includes a plurality of second transistors and the second nano device is oriented parallel to the first nano device. The plurality of second transistors includes at least a second and third source/drains. Forming a gate cut located between the first nano device and the second nano device. Forming a dielectric pillar located between the at least first source/drain of the first nano device and the second source/drain of the second nano device. Forming a source/drain contact connected to the at least one first source/drain and is connected to at least the second source/drains. A portion of the source/drain contact extends parallel to the first nano device and the second nano device.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of multiple nano devices, in accordance with the embodiment of the present invention.

FIG. 2 illustrates a cross section X of the nano stack after the formation of the gate, the source/drains, in accordance with the embodiment of the present invention.

FIG. 3 illustrates a cross section Y1 of the source/drain region after the formation of the gate, the source/drains, in accordance with the embodiment of the present invention.

FIG. 4 illustrates a cross section Y2 of the source/drain region after the formation of the gate, the source/drains, in accordance with the embodiment of the present invention.

FIG. 5 illustrates a top-down view of multiple nano devices after the formation of a gate cut, in accordance with the embodiment of the present invention.

FIG. 6 illustrates a cross section Y1 of the source/drain region after the formation of a gate cut, in accordance with the embodiment of the present invention.

FIG. 7 illustrates a cross section Y2 of the source/drain region after the formation of a gate cut, in accordance with the embodiment of the present invention.

FIG. 8 illustrates a cross section Y1 of the source/drain region after the formation of a dielectric liner and dielectric fill layer, in accordance with the embodiment of the present invention.

FIG. 9 illustrates a cross section Y2 of the source/drain region after the formation of a dielectric liner and dielectric fill layer, in accordance with the embodiment of the present invention.

FIG. 10 illustrates a top-down view of multiple nano devices after the formation sacrificial liner and formation of contact trenches, in accordance with the embodiment of the present invention.

FIG. 11 illustrates a cross section X of the nano stack after the formation sacrificial liner and formation of contact trenches, in accordance with the embodiment of the present invention.

FIG. 12 illustrates a cross section Y1 of the source/drain after the formation sacrificial liner and formation of contact trenches, in accordance with the embodiment of the present invention.

FIG. 13 illustrates a cross section Y2 of the source/drain region after the formation sacrificial liner and formation of contact trenches, in accordance with the embodiment of the present invention.

FIG. 14 illustrates a top-down view of multiple nano devices after filling the contact trench with a lithography layer and pattering the lithography layer, in accordance with the embodiment of the present invention.

FIG. 15 illustrates a cross section X of the source/drain region after filling the contact trench with a lithography layer and pattering the lithography layer, in accordance with the embodiment of the present invention.

FIG. 16 illustrates a cross section Y2 of the source/drain region after filling the contact trench with a lithography layer and pattering the lithography layer, in accordance with the embodiment of the present invention.

FIG. 17 illustrates a top-down view of multiple nano devices after the formation of dielectric pillars and the removal of the lithography layer, in accordance with the embodiment of the present invention.

FIG. 18 illustrates a cross section X of the source/drain region after the formation of dielectric pillars and the removal of the lithography layer, in accordance with the embodiment of the present invention.

FIG. 19 illustrates a cross section Y2 of the source/drain region after the formation of dielectric pillars and the removal of the lithography layer, in accordance with the embodiment of the present invention.

FIG. 20 illustrates a top-down view of multiple nano devices after an isotropic oxide etch of portions of the interlayer dielectric layer, in accordance with the embodiment of the present invention.

FIG. 21 illustrates a cross section Y1 of the source/drain region after an isotropic oxide etch of portions of the interlayer dielectric layer, in accordance with the embodiment of the present invention.

FIG. 22 illustrates a cross section Y2 of the source/drain region after an isotropic oxide etch of portions of the interlayer dielectric layer, in accordance with the embodiment of the present invention.

FIG. 23 illustrates a top-down view of multiple nano devices after the formation of a plurality of contacts, in accordance with the embodiment of the present invention.

FIG. 24 illustrates a cross section X of the nano stack after the formation of a plurality of contacts, in accordance with the embodiment of the present invention.

FIG. 25 illustrates a cross section Y1 of the source/drain after the formation of a plurality of contacts, in accordance with the embodiment of the present invention.

FIG. 26 illustrates a cross section Y2 of the source/drain region after the formation of a plurality of contacts, in accordance with the embodiment of the present invention.

FIG. 27 illustrates a top-down view of multiple nano devices after the formation of a top interlayer dielectric layer and the formation of a plurality of vias, in accordance with the embodiment of the present invention.

FIG. 28 illustrates a cross section X of the nano stack after the formation of a top interlayer dielectric layer and the formation of a plurality of vias, in accordance with the embodiment of the present invention.

FIG. 29 illustrates a cross section Y1 of the source/drain after the formation of a top interlayer dielectric layer and the formation of a plurality of vias, in accordance with the embodiment of the present invention.

FIG. 30 illustrates a cross section Y2 of the source/drain region after the formation of a top interlayer dielectric layer and the formation of a plurality of vias, in accordance with the embodiment of the present invention.

FIG. 31 illustrates a cross section X of the nano stack after the formation of additional top interlayer dielectric material and the formation of metal lines, in accordance with the embodiment of the present invention.

FIG. 32 illustrates a cross section Y1 of the source/drain after the formation of additional top interlayer dielectric material and the formation of metal lines, in accordance with the embodiment of the present invention.

FIG. 33 illustrates a cross section Y2 of the source/drain region after the formation of additional top interlayer dielectric material and the formation of metal lines, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards forming a contact bar within a gate cut, where the contact bar is formed integrally with a source/drain contact. The contact bar provides a large landing for the via contact (VA) formation, such that the landing (i.e., the contact bar) has a width large enough for easy alignment of the VA contact. The VA contact is formed as a bar and has an alignment in a way that the VA contact extends the length of the contact bar. Furthermore, the contact bar is formed within the gate cut, thus a first dielectric liner segment has a portion surrounded by the contact bar and a first source/drain contact. A dielectric pillar is located between the contact bar and a second source/drain contact.

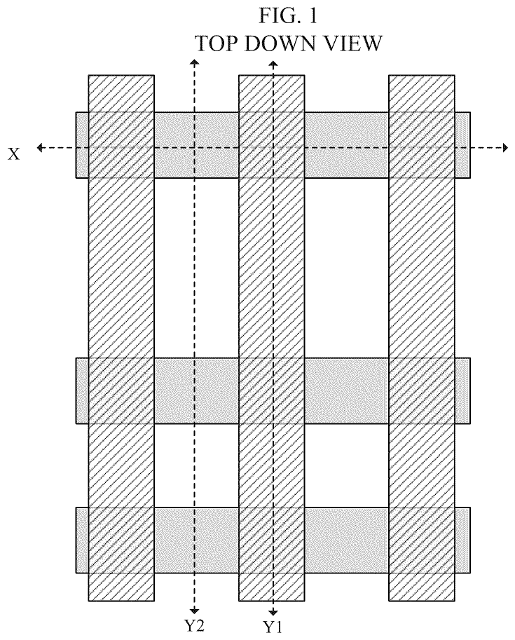

FIG. 1 illustrates a top-down view of multiple devices, in accordance with the embodiment of the present invention. The cross-section X extends horizontally through the nano stacks of one of the devices. Cross section Y1 is perpendicular to cross section X, where cross section Y1 is through a gate region that spans across multiple nano stacks. Cross section Y2 is perpendicular to cross section X, where cross section Y2 is through a source/drain region that spans across multiple nano stacks.

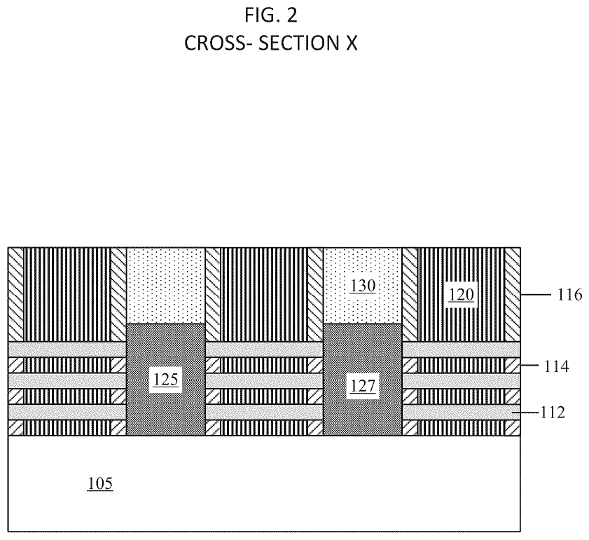

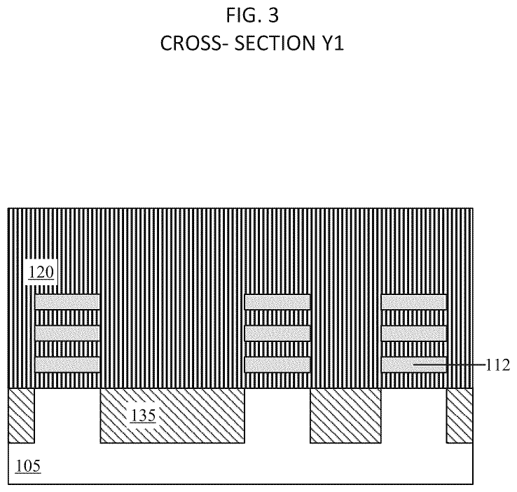

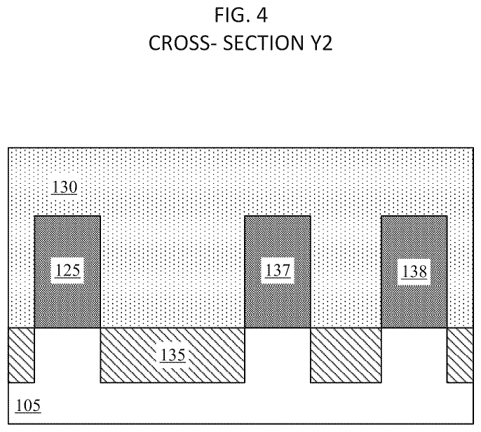

FIGS. 2, 3, and 4 illustrate the processing stage after the formation of the gate, the source/drains. FIG. 2 illustrates a plurality of transistors that includes a substrate 105, a plurality of channel layers 112, an inner spacer 114, a top spacer 116, a gate 120, a first source/drain 125, a second source/drain 127, a third source/drain 137, a fourth source/drain 138, an interlayer dielectric layer 130, and a shallow trench isolation layer 135.

The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the first substrate 105 and the second substrate 108. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor substrate 105 may be doped, undoped or contain doped regions and undoped regions therein.

The first source/drain 125, the second source/drain 127, the third source/drain 137, and the fourth source/drain 138 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

The gate 120 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

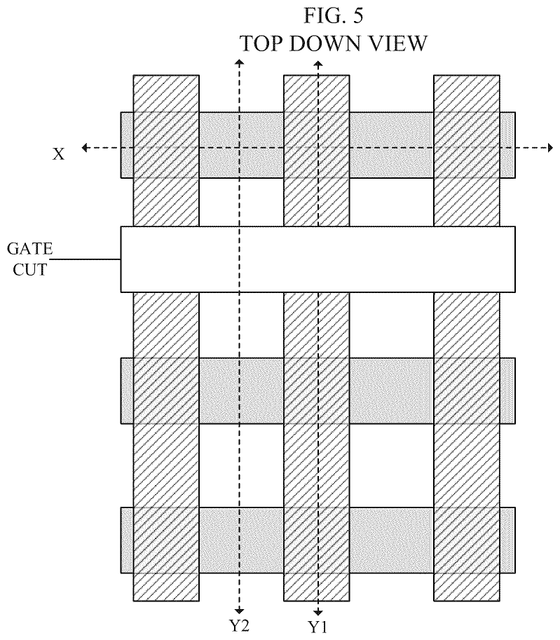

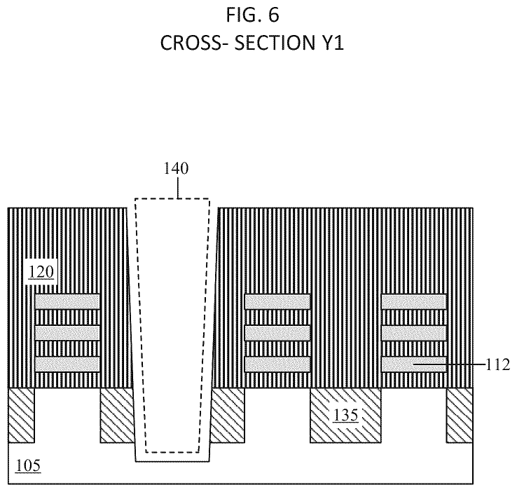

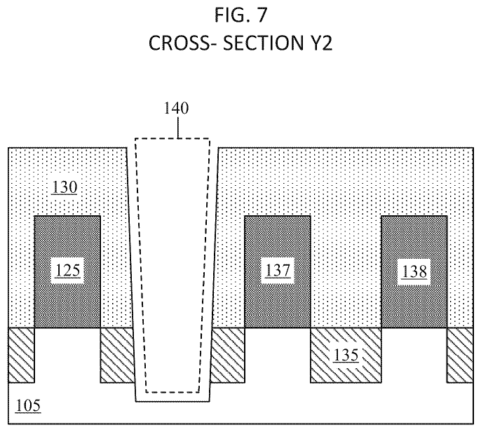

FIGS. 5, 6, and 7 illustrate the processing stage after the formation of a gate cut 140. A gate cut 140 is formed in the gate 120, the interlayer dielectric layer 130, the shallow trench isolation layer 135, and the substrate 105. The gate cut 140 is aligned between two the nano stack columns as illustrated by FIG. 5.

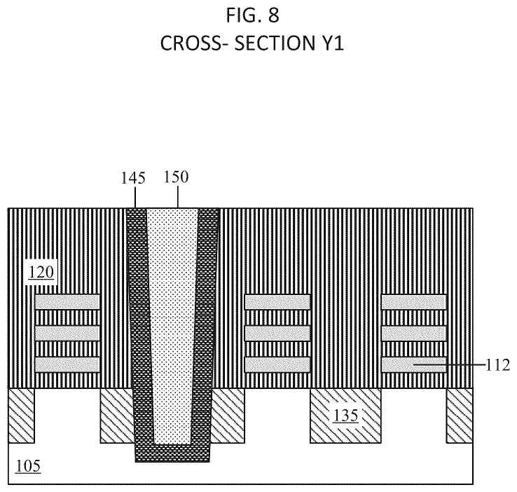

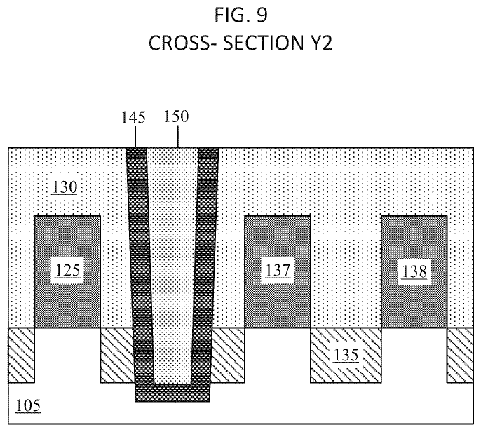

FIGS. 8 and 9 illustrate the processing stage after the formation of a dielectric liner 145 and dielectric fill layer 150. A dielectric liner 145 is formed along the sidewalls and a bottom wall of the gate cut 140. The dielectric liner 145 includes at least two vertical segments and a bottom segment that lines the gate cut 140. The dielectric liner 145 can be comprised of, for example, SiN, SiBCN, SiOCN, SiC, SiOC, etc. A dielectric fill layer 150 is formed within the remaining space located between the segments of the dielectric liner 145 within the gate cut 140. The dielectric fill layer 150 can be comprised of, for example, SiO₂. Excess dielectric liner 145 and dielectric fill layer 150 is removed, for example, by a chemical-mechanical planarization (CMP) process.

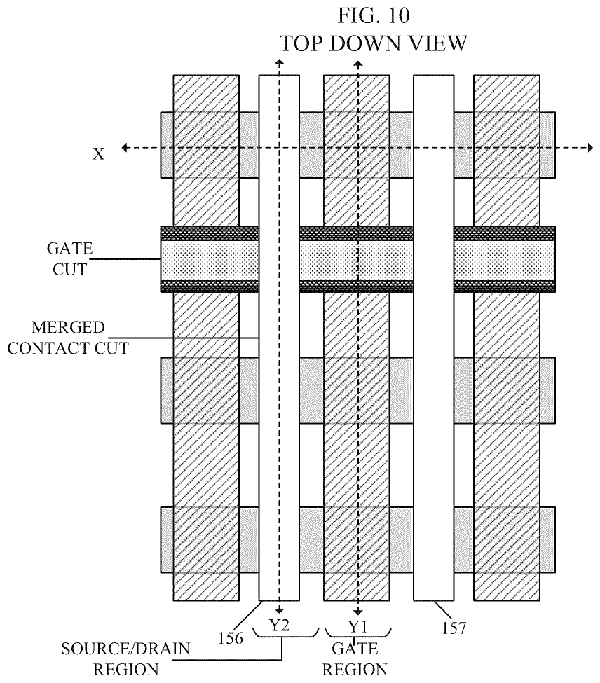

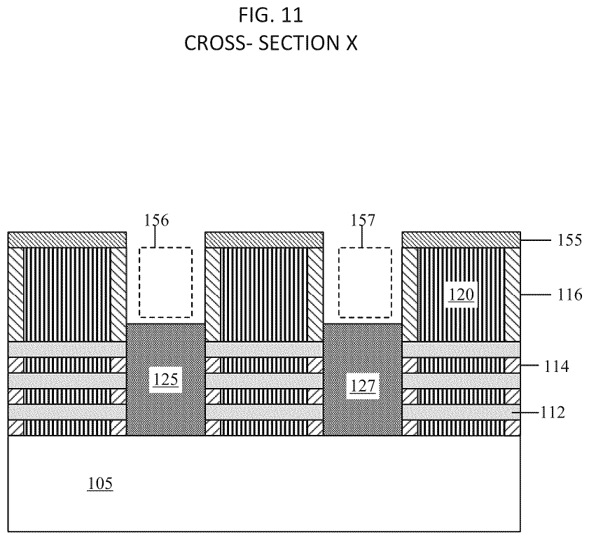

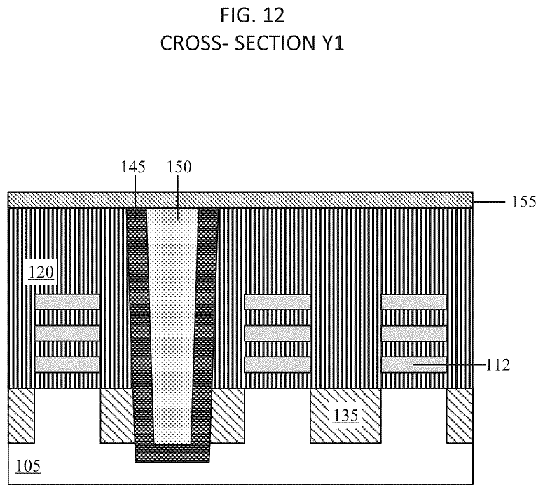

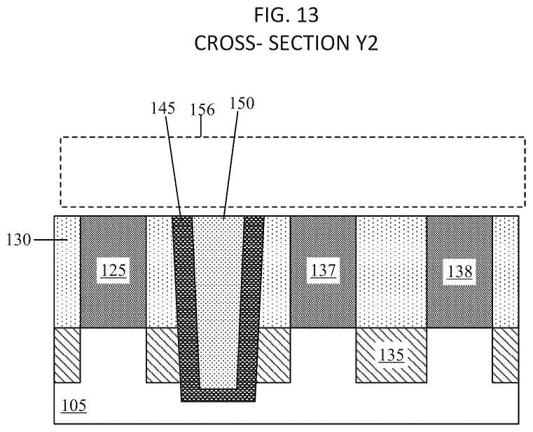

FIGS. 10, 11, 12, and 13 illustrate the processing stage after the formation of a sacrificial liner 155 and formation of contact trenches 156, 157. A sacrificial liner 155 is formed on top of the top surfaces of the gate 120, the top spacer 116, the dielectric liner 1345, and the dielectric fill layer 150. Contact trenches 156 and 157 are formed in the source/drain region, where one of the contact trenches 156 is located between two of the gate regions. The contact trenches 156 and 157 are perpendicular to the gate cut as illustrated by FIG. 10. The contact trench 156 pulls down portions of the dielectric liner 145 and the dielectric fill layer 150 as illustrated by FIG. 13.

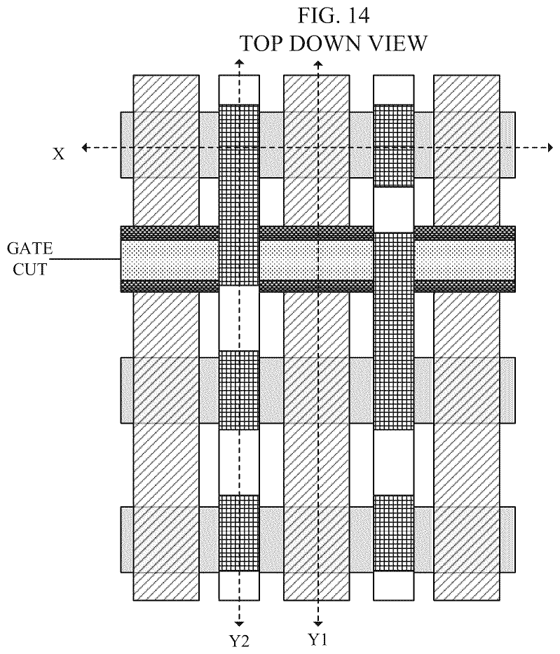

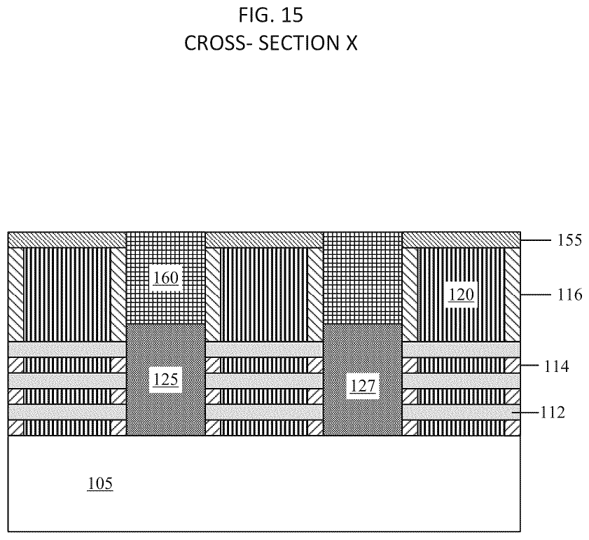

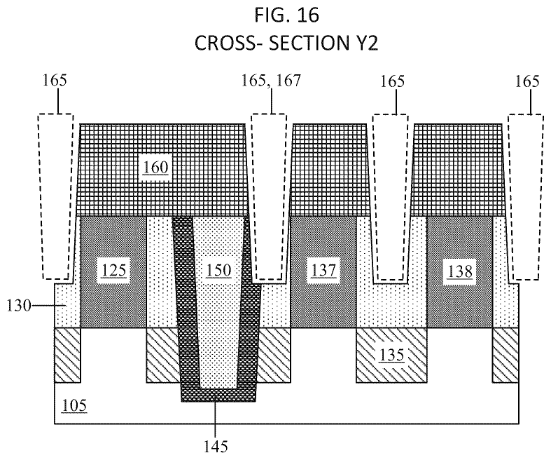

FIGS. 14, 15, and 16 illustrate the processing stage after filling the contact trenches 156 and 157 with a lithography layer 160 and pattering the lithography layer 160. The contact trenches 156 and 157 are filled in with a lithography layer 160. The lithography layer 160 is patterned to form a plurality of trenches/holes 165 in the lithography layer 160 and the interlayer dielectric layer 130. Trench/hole 167 extends in into the interlayer dielectric layer 130 and into to one of the vertical segments of the dielectric liner 145.

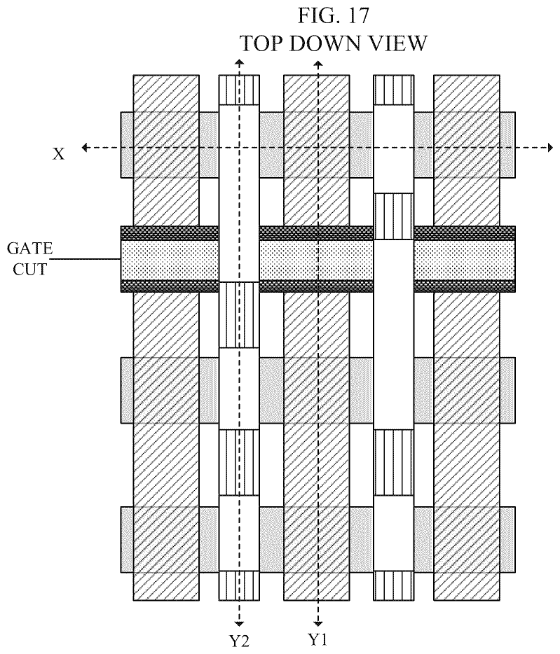

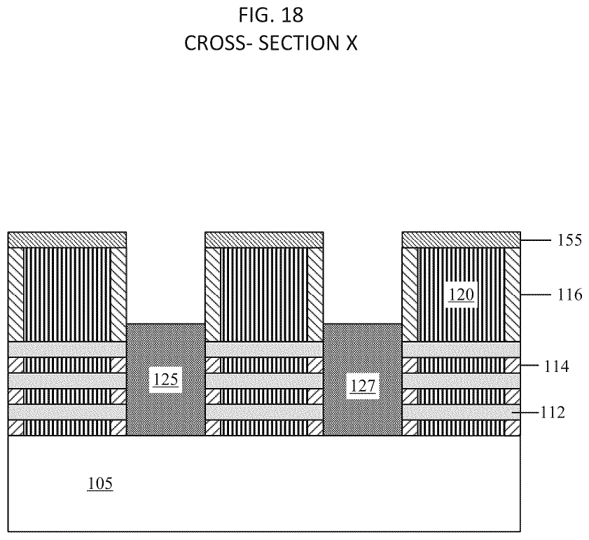

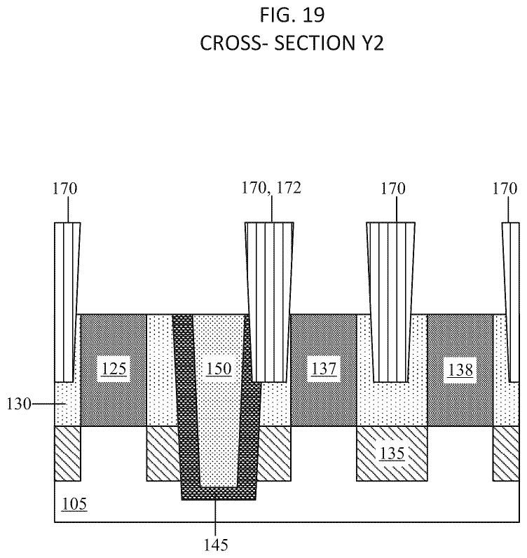

FIGS. 17, 18, and 19 illustrate the processing stage after the formation of dielectric pillars 170, 172 and the removal of the lithography layer 160. The trenches/holes 165, 167 are filled with a dielectric material to form a plurality of dielectric pillars 170, 172. These dielectric pillars 170 act as a contact cut that separates the different contacts. Dielectric pillar 172 extends the height of one of the vertical segments of the dielectric liner 145. Thus, the dielectric pillar 172 acts as an extension of one of the vertical segments of the dielectric liner 145, causing the dielectric liner 145 to have a first vertical segment at a first height and a second vertical segment at a second higher height (i.e., the combined height of the dielectric pillar 172 and the vertical segment of dielectric liner 145).

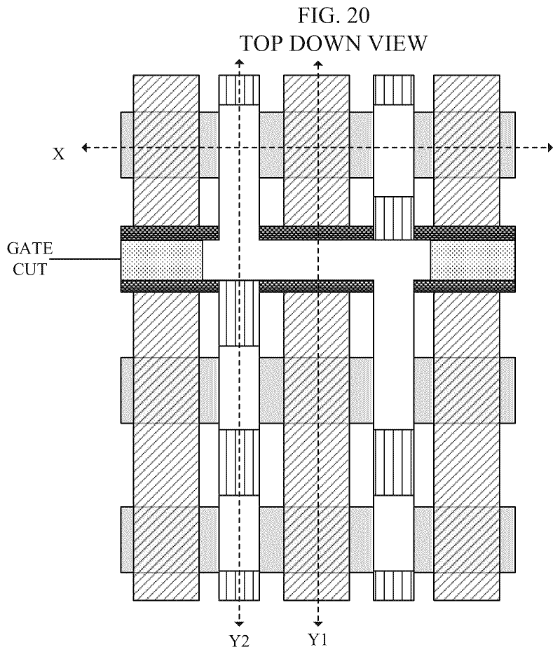

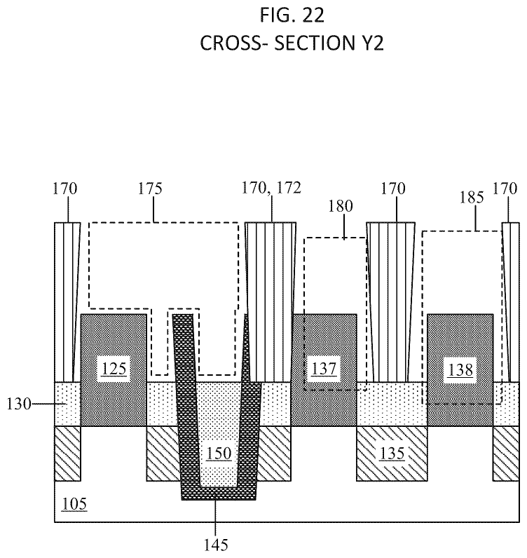

FIGS. 20, 21, and 22 illustrate the processing stage after an isotropic oxide etch of portions of the interlayer dielectric layer 130. An isotropic oxide etch process is used to remove portions of the interlayer dielectric layer 130 to from a plurality of contact trenches. The interlayer dielectric layer 130 is not completely removed, but only the height is lowered to expose areas located around the first source/drain 125, the second source/drain 127, the third source/drain 137, and the fourth source/drain 138 as illustrated by FIGS. 20 and 22. Portions of the sidewalls of each of the first source/drain 125, the second source/drain 127, the third source/drain 137, and the fourth source/drain 138, is exposed, respectively. Contact trench 185 illustrates how multiple sidewalls of the fourth source/drain 138 are exposed by the lowering of the interlayer dielectric layer 130. Contact trench 180 illustrates how one sidewall of the third source/drain 137 is exposed by the lowering of the interlayer dielectric layer 130. The dielectric pillar 172 prevents the exposure of one of the sidewalls of the third source/drain 137. The placement of the dielectric pillars 170 determines if one or multiple sidewalls of the source/drains will be exposed by the lowering of the interlayer dielectric layer 130.

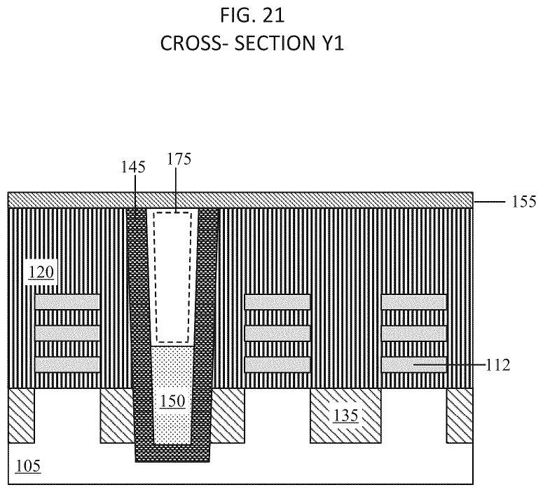

The contact trench 174 is formed by lowering the interlayer dielectric layer 130 located around the first source/drain 125 and by removal of portions of the dielectric fill layer 150 contained within the dielectric liner 145. The removal of portions of the dielectric fill layer 150 and the interlayer dielectric layer 130 causes a contact trench 175 to extend over the first source/drain 125 and over one of the vertical segments of the dielectric liner 145. The contact trench 175 exposes a portion of the sidewalls of the vertical segment of the dielectric liner 145. The dielectric pillar 172 acts as an extension of one of the vertical segments of the dielectric liner 145, thus the dielectric pillar 172 separates the different contact trenches 175 and 180. Contact trench 175 has at least one protrusion that extend over one more source/drain regions (i.e., the first source/drain 125) as illustrated by FIG. 20. The contact trench 175 further comprises a bar trench that extends within the gate cut as illustrated in FIGS. 20 and 21. The bar trench of the contact trench 175 is parallel to the with the adjacent nano devices. FIG. 21 shows how contact trench 175 extends under the sacrificial liner 155. The bar trench of the contact trench 175 will allow for the formation of the contact bar 190B which will be described in further detail below.

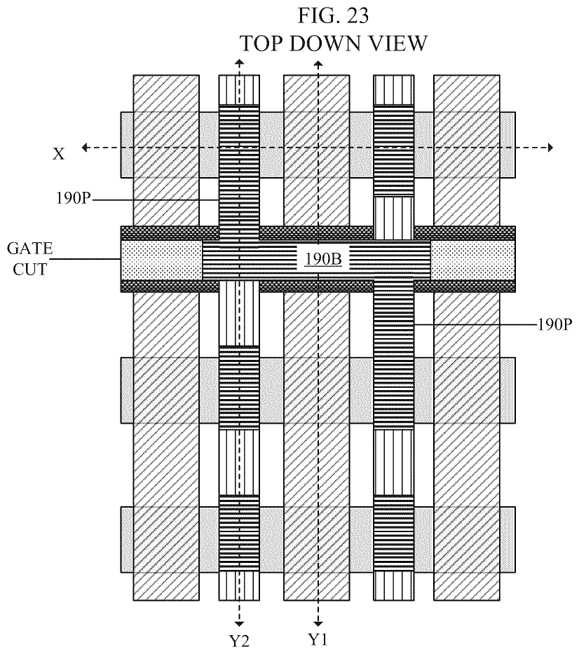

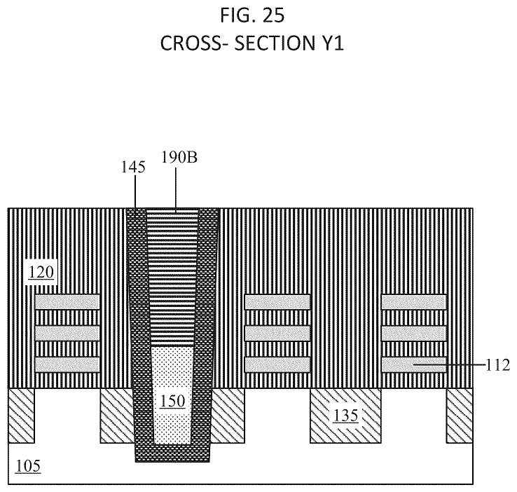

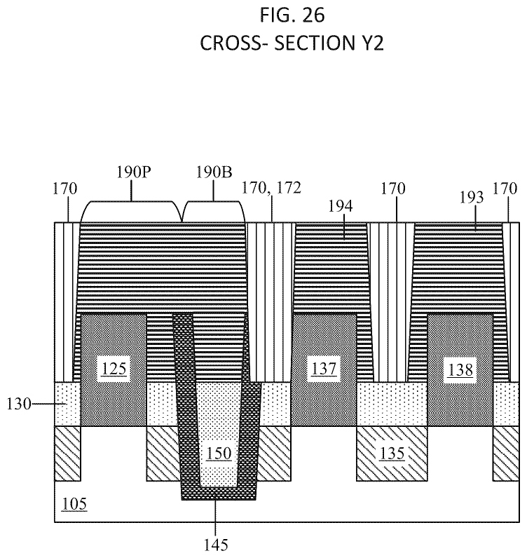

FIGS. 23, 24, 25, and 26 illustrate the processing stage after the formation of a plurality of contacts. The plurality of contact trenches 175, 180, and 185 and others are filled with a conductive metal to form a plurality of contacts, the sacrificial liner 155 is removed during contact metal CMP. The first contact is comprised of a contact bar 190B and contact protrusions 190P, where the contact bar 190B extends within the gate cut and the contact protrusions 190P extend off the contact bar 190B into the source/drain regions as illustrated by FIG. 23. The first contact has at least one protrusion 190P (two are illustrated in FIG. 23) that extends off the contact bar 190B into the source/drain regions. FIGS. 23, 24 and 26 illustrates that contact protrusion 190P extends over and around the first source/drain 125. Furthermore, the contact protrusion 190P and the contact bar 190B surrounds a portion of one of the vertical segments of the dielectric liner 145. As illustrated in FIG. 23, multiple contact protrusions 190P extend off the contact bar 190B, where the contact protrusion 190P are offset from each other. The contact bar 190B is flush against a sidewall of both vertical segments of the dielectric liner 145. Furthermore, the contact bar 190B is flush against a sidewall of the dielectric pillar 172. The bottom surface of the contact bar 190 is in contact with a top surface of the dielectric fill layer 150. The bottom surface of the contact protrusion 190P is in contact with the interlayer dielectric layer 130 and the first source/drain 125. The combined length of the contact protrusion 190P and the width of the contact bar 190B, causes the conductive metal to be located above and around a portion of one of the vertical segments of the dielectric liner (as illustrated in FIG. 26). FIG. 25 illustrates how the contact bar 190B is located on top of the dielectric fill layer 150 and located between the vertical segments of the dielectric liner 145. The vertical segments of the dielectric liner 145 separate the contact bar 190B from the gate 120.

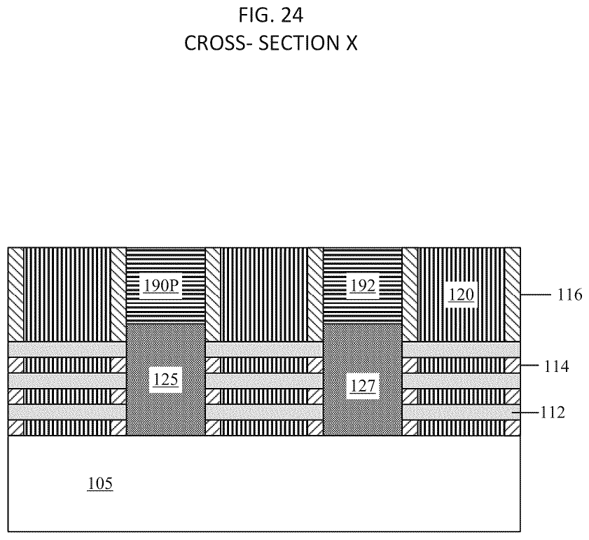

A contact 192 is formed on top of the second source/drain 127 as illustrated in FIG. 24. FIG. 26 illustrates how the dielectric pillars 170 act as spacers between the different contacts. Contact 194 is formed on top of the third source/drain 137, where contact 194 extends downwards along a sidewall of the third source/drain 194. Contact 194 is located between two dielectric pillars 170, thus isolating contact 194 from the surrounding contact, thus preventing shots between the contacts. Contact 194 has a sidewall flush against dielectric pillar 172, thus dielectric pillar 172 separates the contact bar 190B and contact 194. Contact 193 is formed on top of the fourth source/drain 138, where contact 193 extends downwards along multiple sidewalls of the fourth source/drain 138. The placement/orientation of the dielectric pillars 170 determines how the contacts wrap around the sidewalls of the source/drains.

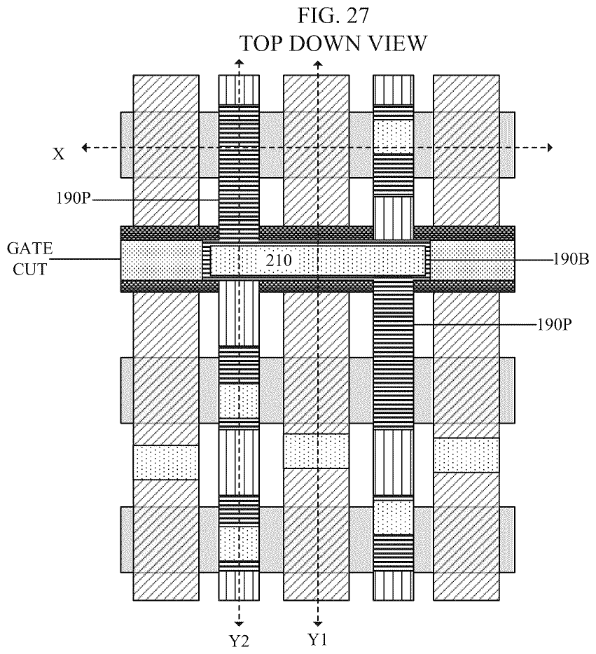

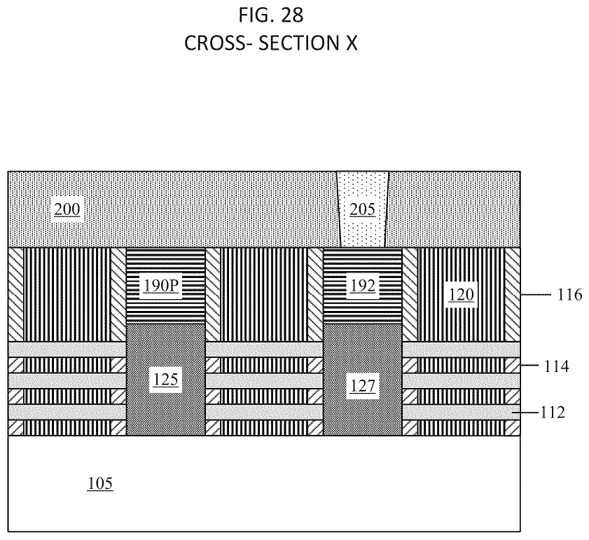

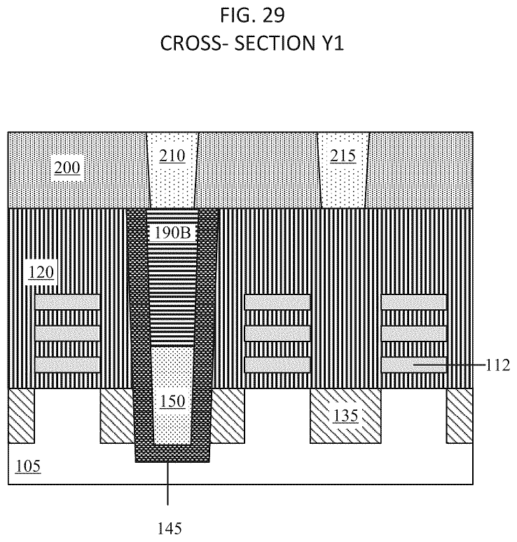

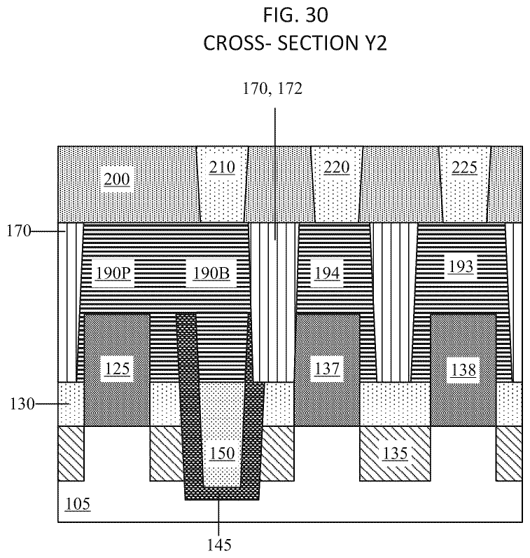

FIGS. 27, 28, 29, and 30 illustrate the processing stage after the formation of a top interlayer dielectric layer 200 and the formation of a plurality of vias. A top interlayer dielectric layer 200 is formed on top of the gate 120, the upper spacer 115, the contact protrusion 190P, the contact bar 190B, contacts 192, 194, 190, and the dielectric pillars 170. A plurality of holes (not shown) is formed in in the top interlayer dielectric layer 200. These holes are filled in with a conductive metal to form source/drain contacts 200, 225, 205, and gate contact 215. A trench (not shown) is formed in the top interlayer dielectric layer 200, where the trench (not shown) is orientated above the contact bar 190B as illustrated in FIG. 27. The trench is filled with a conductive metal to form a contact bar via 210. The length of the contact bar 190B allows for easier alignment of the contact bar via 210 because of the increased landing size of the contact bar 190B. The contact bar via 210 extends along the length of contact bar 190B as illustrated in FIG. 27.

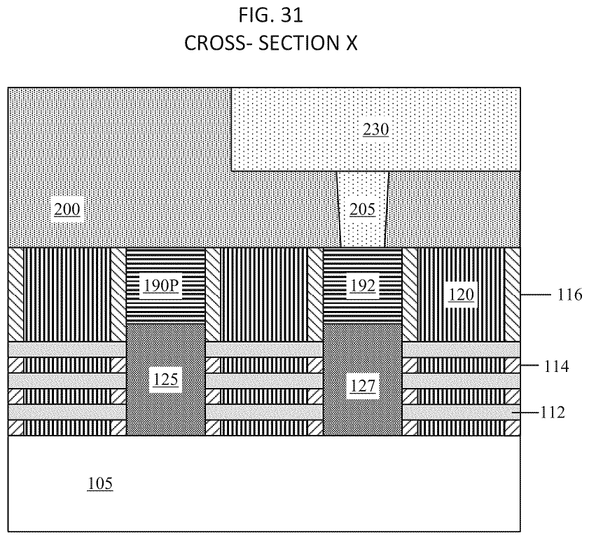

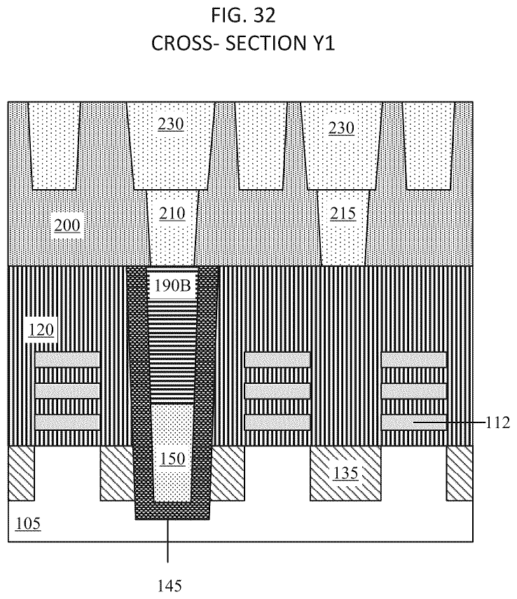

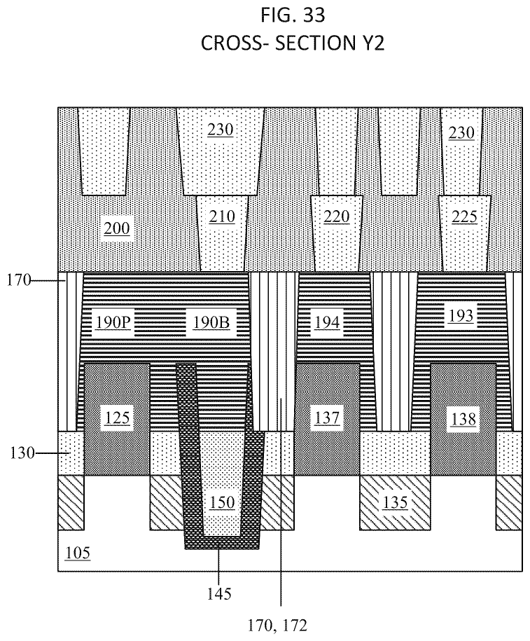

FIGS. 31, 32, and 33 illustrate the processing stage after the formation of additional top interlayer dielectric material and the formation of metal lines 230. Additional top interlayer dielectric layer 200 material is deposited to increase the height of the top interlayer dielectric layer 200. Trenches (not shown) are formed in the top interlayer dielectric layer 200, where the trenches expose the top surface of the source/drain contacts 200, 225, 205, and gate contact 215. The trenches are filled in with a conductive metal to form the metal lines 230.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first nano device that includes a plurality of first transistors, wherein the plurality of first transistors includes at least one first source/drain;
a second nano device includes a plurality of second transistors, wherein the second nano device is oriented parallel to the first nano device, wherein the plurality of second transistors includes at least two second source/drains;
a gate cut located between the first nano device and the second nano device; and
a source/drain contact connected to the at least one first source/drain and is connected to at least one of the at least two second source/drains, wherein a portion of the source/drain contact extends parallel to the first nano device and the second nano device.

2. The microelectronic structure of claim 1, wherein the gate cut comprises:
a dielectric liner, wherein the dielectric liner is includes a first vertical segment, a second vertical segment, and a bottom segment; and
a dielectric fill layer located between the first vertical segment and the second vertical segments and located on top of the bottom segment.

3. The microelectronic structure of claim 2, wherein the source/drain contact includes a bar section that is located on top of the dielectric fill layer.

4. The microelectronic structure of claim 3, wherein the source/drain contact is in contact with a top wall and sidewalls of a portion of the first vertical segment of the dielectric liner.

5. The microelectronic structure of claim 4, wherein the source/drain contact includes a first protrusion and a second protrusion that extends off the bar section of the source/drain contact.

6. The microelectronic structure of claim 5, wherein the first protrusion is in contact with the at least one first source/drain, and wherein the second protrusion is in contact with the at least one of the at least two second source/drains.

7. The microelectronic structure of claim 6, wherein the first protrusion and the second protrusion are offset from each other.

8. A microelectronic structure comprising:
a first nano device that includes a plurality of first transistors, wherein the plurality of first transistors includes at least one first source/drain;
a second nano device includes a plurality of second transistors, wherein the second nano device is oriented parallel to the first nano device, wherein the plurality of second transistors includes at least a second and a third source/drains;
a gate cut located between the first nano device and the second nano device;
a first source/drain contact connected to the at least one first source/drain and is connected to at least the second source/drains, wherein a portion of the source/drain contact extends parallel to the first nano device and the second nano device; and
a dielectric pillar located between the at least one first source/drain of the first nano device and the at least second source/drain of the second nano device.

9. The microelectronic structure of claim 8, wherein the gate cut comprises:
a dielectric liner, wherein the dielectric liner is includes a first vertical segment, a second vertical segment, and a bottom segment; and
a dielectric fill layer located between the first vertical segment and second vertical segments and located on top of the bottom segment.

10. The microelectronic structure of claim 9, wherein the first source/drain contact includes a bar section that is located on top of the dielectric fill layer.

11. The microelectronic structure of claim 10, wherein the source/drain contact is in contact with a top wall and sidewalls of a portion of the first vertical segment of the dielectric liner.

12. The microelectron structure of claim 11, wherein the dielectric pillar extends vertically from the second vertical segment of the dielectric liner.

13. The microelectronic structure of claim 12, wherein the bar section of the first source/drain contact is flush against a sidewall of the second vertical segment, and wherein the bar section of the first source/drain contact is flush against a first sidewall of the dielectric pillar.

14. The microelectronic structure of claim 13, further comprising:
a second source/drain contact that is connected to the third source/drain.

15. The microelectronic structure of claim 14, wherein the second source/drain contact is flush against a second sidewall of the dielectric pillar, and wherein the dielectric pillar separates the bar section of the first source/drain contact and the second source/drain contact.

16. The microelectronic structure of claim 15 wherein the at least one first source/drain contact includes a first protrusion and a second protrusion that extends off the bar section.

17. The microelectronic structure of claim 16, wherein the first protrusion is in contact with the at least one first source/drain, and wherein the second protrusion is in contact with the at least one of the at least second source/drains.

18. The microelectronic structure of claim 17, wherein the first protrusion and the second protrusion are offset from each other.

19. A method comprising:
forming a first nano device that includes a plurality of first transistors, wherein the plurality of first transistors includes at least one first source/drain;
forming a second nano device includes a plurality of second transistors, wherein the second nano device is oriented parallel to the first nano device, wherein the plurality of second transistors includes at least a second and a third source/drains;
forming a gate cut located between the first nano device and the second nano device;
forming a dielectric pillar located between the at least one first source/drain of the first nano device and the second source/drain of the second nano device; and
forming a source/drain contact connected to the at least one first source/drain and is connected to the second source/drain, wherein a portion of the source/drain contact extends parallel to the first nano device and the second nano device.

20. The method of claim 19, further comprising:
wherein the gate cut comprises:
a dielectric liner, wherein the dielectric liner is includes a first vertical segment, a second vertical segment, and a bottom segment; and
a dielectric fill layer located between the first and second vertical segments and located on top of the bottom segment;
wherein the source/drain contact includes a bar section that is located on top of the dielectric fill layer; and
wherein the dielectric pillar extends vertically from the second vertical segment of the dielectric liner.
